(19) United States
(12) Patent Application Publication
(10) Pub. No.: US 2026/0360437 A1
(43) Pub. Date: Nov. 12, 2026

(54) SWITCHING CIRCUIT AND ASSOCIATED SWITCHING CONTROL METHOD FOR NONVOLATILE MEMORY

(71) Applicant: eMemory Technology Inc., Hsin-Chu (TW)

(72) Inventors: Wei-Chiang ONG, Hsinchu County (TW); Chieh LEE, Hsinchu County (TW); Wei-Ming CHIU, Hsinchu County (TW)

(21) Appl. No.: 19/672,957

(22) Filed: May 11, 2026

Related U.S. Application Data
(60) Provisional application No. 63/804,007, filed on May 12, 2025.

(51) Int. Cl. G11C 16/12; G11C 16/04; G11C 16/30; H03K 19/0185

(52) U.S. Cl. CPC G11C 16/12; G11C 16/0433; G11C 16/30; H03K 19/018521

(57) ABSTRACT

A switching circuit of a nonvolatile memory includes a plurality of switching devices. The switching device of the switching circuit includes a selection circuit, a level shifter and a converting circuit. The selection circuit receives a programming voltage and a non-programming voltage. The selection circuit is coupled to a control gate line. The level shifter receives a control signal and an inverted control signal. The level shifter is connected with the selection circuit. The converting circuit receives the inverted control signal. The converting circuit is connected with the level shifter and the selection circuit. When a program action is performed, the level shifter and the converting circuit control the selection circuit according to the control signal and the inverted control signal. Consequently, the selection circuit provides one of the programming voltage and the non-programming voltage to the control gate line.

This application claims the benefit of US provisional application Serial No. 63/804,007, filed May 12, 2025, the subject matters of which is incorporated herein by reference.

### FIELD OF THE INVENTION

The present invention relates to a circuit for a memory, and more particularly to a switching circuit and an associated switching control method for a nonvolatile memory.

### BACKGROUND OF THE INVENTION

Generally, nonvolatile memory cells can be classified into multi-time programmable memory cells (also referred as MTP memory cells), one-time programmable memory cells (also referred as OTP memory cells) and mask read only memory cells (also referred as Mask ROM cells).

Generally, the MTP memory cells can be programmed many times, and the stored data of the MTP memory cells can be modified many times. Furthermore, a plurality of MTP memory cells can be formed as a memory cell array, and the memory cell array and associated peripheral circuits can be formed as a multi-time programmable nonvolatile memory (also referred as a MTP nonvolatile memory).

For example, a memory cell composed of a SONOS transistor (silicon-oxide-nitride-oxide-silicon transistor) is a multi-time programmable memory cell. The gate structure of the SONOS transistor includes a stacked structure comprising an oxide layer, a nitride layer and another oxide layer. The nitride layer is used as a charge storage layer.

Furthermore, by providing proper bias voltages to program or erase the memory cell, the memory cell can be selectively in one of two different storage states. For example, during a program action, carriers (e.g., electrons) are injected into the charge storage layer of the SONOS transistor. During an erase action, carriers are ejected from the charge storage layer of the SONOS transistor.

### SUMMARY OF THE INVENTION

An embodiment of the present invention provides a switching circuit of a nonvolatile memory including a plurality of switching devices. The plurality of switching devices are respectively connected with a plurality of control gate lines in a memory cell array. A first switching device of the switching circuit is coupled to a first control gate line. The first switching device includes a selection circuit, a level shifter and a converting circuit. The selection circuit receives a programming voltage and a non-programming voltage. The selection circuit is coupled to the first control gate line. The level shifter receives a first control signal and a first inverted control signal. The level shifter is connected with the selection circuit. The first control signal and the first inverted control signal are complementary to each other. The converting circuit receives the first inverted control signal. The converting circuit is connected with the level shifter and the selection circuit. When a program action is performed, the level shifter and the converting circuit control the selection circuit according to the first control signal and the first inverted control signal. Consequently, the selection circuit provides one of the programming voltage and the non-programming voltage to the first control gate line.

Numerous objects, features and advantages of the present invention will be readily apparent upon a reading of the following detailed description of embodiments of the present invention when taken in conjunction with the accompanying drawings. However, the drawings employed herein are for the purpose of descriptions and should not be regarded as limiting.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1A is a schematic circuit diagram illustrating the architecture of a memory cell array comprising SONOS transistors;

FIG. 1B schematically illustrates associated bias voltages for performing a program action on the memory cell of the memory cell array;

FIG. 1C is a schematic circuit diagram illustrating the architecture of a nonvolatile memory;

FIG. 2A is a schematic circuit diagram illustrating the switching device of the switching circuit in the nonvolatile memory of the present invention;

FIG. 2B is a schematic circuit diagram illustrating a high voltage generator and a low voltage generator of the switching circuit in the nonvolatile memory of the present invention;

FIG. 3 is a schematic circuit diagram illustrating the level shifter and the converting circuit in the switching device according to a first embodiment of the present invention;

FIGS. 4A, 4B, 4C and 4D are schematic circuit diagrams illustrating the operations of the switching device in the switching circuit of the present invention;

FIG. 5 is a schematic circuit diagram illustrating the level shifter and the converting circuit in the switching device according to a second embodiment of the present invention; and

FIG. 6 is a schematic circuit diagram illustrating the level shifter and the converting circuit in the switching device according to a third embodiment of the present invention.

### DETAILED DESCRIPTION OF PREFERRED EMBODIMENTS

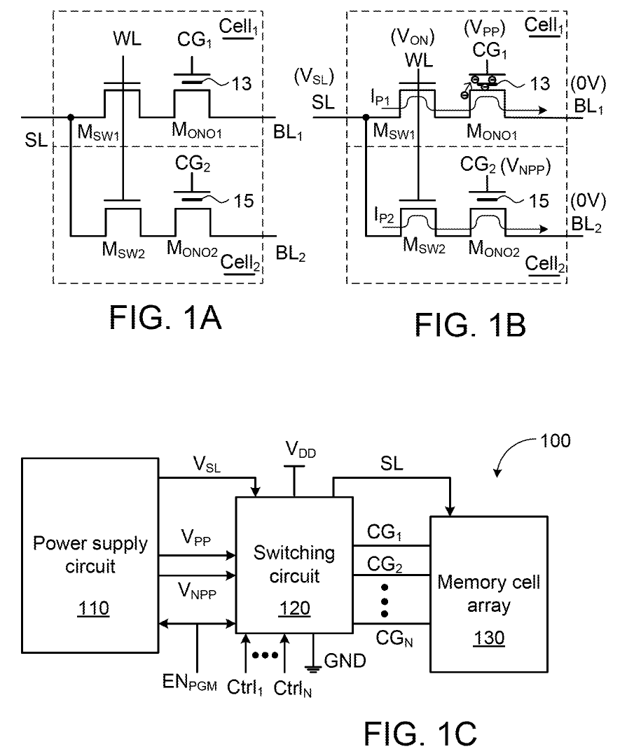

FIG. 1A is a schematic circuit diagram illustrating the architecture of a memory cell array comprising SONOS transistors. The memory cell array includes two memory cells Cell₁ and Cell₂. The two memory cells Cell₁ and Cell₂ have the same circuitry structure.

The memory cell Cell₁ includes a switch transistor M_{SW1} and a SONOS transistor M_{ONO1}. The memory cell Cell₂ includes a switch transistor M_{SW2} and a SONOS transistor M_{ONO2}. The SONOS transistor M_{ONO1} includes a charge storage layer 13. The SONOS transistor M_{ONO2} includes a charge storage layer 15.

The first drain/source terminal of switching transistor M_{SW1} is connected with a source line SL. The gate terminal of switching transistor M_{SW1} is connected with a word line WL. The first drain/source terminal of the SONOS transistor M_{ONO1} is connected with the second drain/source terminal of switching transistor M_{SW1}. The gate terminal of the SONOS transistor M_{ONO1} is connected with a control gate line CG₁. The second drain/source terminal of the SONOS transistor M_{ONO1} is connected with a first bit line BL₁. Similarly, the first drain/source terminal of the switching transistor M_{SW2} is connected with the source line SL. The gate terminal of switching transistor M_{SW2} is connected with the word line WL. The first drain/source terminal of the SONOS transistor M_{ONO2} is connected with the second drain/source terminal of the switching transistor M_{SW2}. The gate terminal of the SONOS transistor M_{ONO2} is connected with a control gate line CG₂. The second drain/source terminal of SONOS transistor M_{ONO2} is connected with a second bit line BL₂.

For brevity, only two memory cells Cell₁ and Cell₂ in the memory cell array are shown in FIG. 1A. Of course, the memory cell array in FIG. 1A can be expanded to a memory cell array comprising N memory cells. The N memory cells are connected with the same word line. In addition, the N memory cells are connected with corresponding N bit lines and corresponding N control gate lines. Similarly, the memory cell array can be expanded to a memory cell array comprising M×N memory cells, wherein M and N are positive integers greater than 1. That is, the memory cell array includes M word lines, and each word line is connected with N memory cells.

FIG. 1B schematically illustrates associated bias voltages for performing a program action on the memory cell of the memory cell array. For example, during the program action, the carriers are controlled to be injected into the charge storage layer 13 of the SONOS transistor M_{ONO1}, and the carriers are not injected into the charge storage layer 15 of the SONOS transistor M_{ONO2}.

During the program action, the word line WL receives a turn-on voltage V_{ON}, the source line SL receives a source line voltage V_{SL}, the two bit lines BL₁ and BL₂ receive a ground voltage (0V), the control gate line CG₁ receives a programming voltage V_{PP}, and the control gate line CG₂ receives a non-programming voltage V_{NPP}. For example, the turn-on voltage V_{ON} is approximately 1.0V, the source line voltage V_{SL} is equal to the non-programming voltage V_{NPP}, which is approximately 4.5V, and the programming voltage V_{PP} is a variable voltage. For example, the programming voltage V_{PP} ramps up from 2V to a maximum value of 7V, and then the programming voltage V_{PP} ramps down from 7V to 2V. In other words, the programming voltage V_{PP} will fluctuate between 2V and 7V.

Please refer to FIG. 1B again. In the memory cell Cell₁, the switching transistor M_{SW1} is turned on, and a first program current I_{P1} is generated in the region between the source line SL and the first bit line BL₁. When the first program current I_{P1} flows through a channel region of the SONOS transistor M_{ONO1}, the programming voltage V_{PP} controls the carriers to be injected into the charge storage layer 13. Consequently, the memory cell Cell₁ becomes a programmed state. In the memory cell Cell₂, the switching transistor M_{SW2} is turned on, and a second program current I_{P2} is generated in the region between the source line SL and the second bit line BL₂. Since carriers cannot be injected into the charge storage layer 15 in response to the non-programming voltage V_{NPP}, the memory cell Cell₂ becomes an unprogrammed state.

As mentioned above, the memory cells Cell₁ and Cell₂ are controlled to be selectively in the programmed state or the unprogrammed state during the program action. Furthermore, the nonvolatile memory is equipped with a power supply circuit and a switching circuit.

FIG. 1C is a schematic circuit diagram illustrating the architecture of a nonvolatile memory. As shown in FIG. 1C, the nonvolatile memory includes a power supply circuit 110, a switching circuit 120 and a memory cell array 130. The power supply circuit 110 is connected with the switching circuit 120. The switching circuit 120 is connected with a memory cell array 130. The memory cell array 130 at least includes N memory cells. The N memory cells are connected with the corresponding N control gate lines CG₁~CG_{N}, respectively.

The power supply circuit 110 can generate the source line voltage V_{SL}, the programming voltage V_{PP} and the non-programming voltage V_{NPP}. The switching circuit 120 receives a supply voltage V_{DD}, the ground voltage GND, the source line voltage V_{SL}, the programming voltage V_{PP} and the non-programming voltage V_{NPP}. Furthermore, the power supply circuit 110 and the switching circuit 120 receive a program enable signal EN_{PGM}. The switching circuit 120 receives N control signals Ctrl₁~Ctrl_{N}.

During the program action, the program enable signal EN_{PGM} is activated, and the switching circuit 120 transmits the source line voltage V_{SL} to the source line SL. According to N control signals Ctrl₁~Ctrl_{N}, the switching circuit 120 transmits one of the programming voltage V_{PP} and the non-programming voltage V_{NPP} to the corresponding N control gate lines CG₁~CG_{N}.

In an embodiment, the switching circuit 120 includes N switching devices, which have the same structure. Furthermore, the N switching devices receive corresponding control signals and are connected with the corresponding control gate lines. For example, the first switching device receives the control signal Ctrl₁, and the first switching device is coupled to the control gate line CG₁. During the program action, the first switching device receives the control signal Ctrl₁. When the control signal Ctrl₁ is in a first logic level state, the first switching device outputs the programming voltage V_{PP} to the control gate line CG₁ and transmits the programming voltage V_{PP} to the memory cell Cell₁ in the memory cell array 130. Conversely, when the control signal Ctrl₁ is in a second logic level state, the first switching device outputs the non-programming voltage V_{NPP} to the control gate line CG₁ and transmits the non-programming voltage V_{NPP} to the memory cell Cell₁ in the memory cell array 130. That is, during the program action, the first switching device controls the memory cell Cell₁ to be in the programmed state or the unprogrammed state according to the control signal Ctrl₁. Similarly, the second switching device controls the memory cell Cell₂ to be in the programmed state or the unprogrammed state according to the control signal Ctrl₂. That is, during the program action, the switching circuit 120 can control the storage states of the corresponding N memory cells Cell₁~Cell_{N} according to the N control signals Ctrl₁~Ctrl_{N}.

The detailed circuitry structure of the switching circuit 120 will be described as follows. Since the N switching devices in the switching circuit 120 have the same structure, only a single switching device will be illustrated.

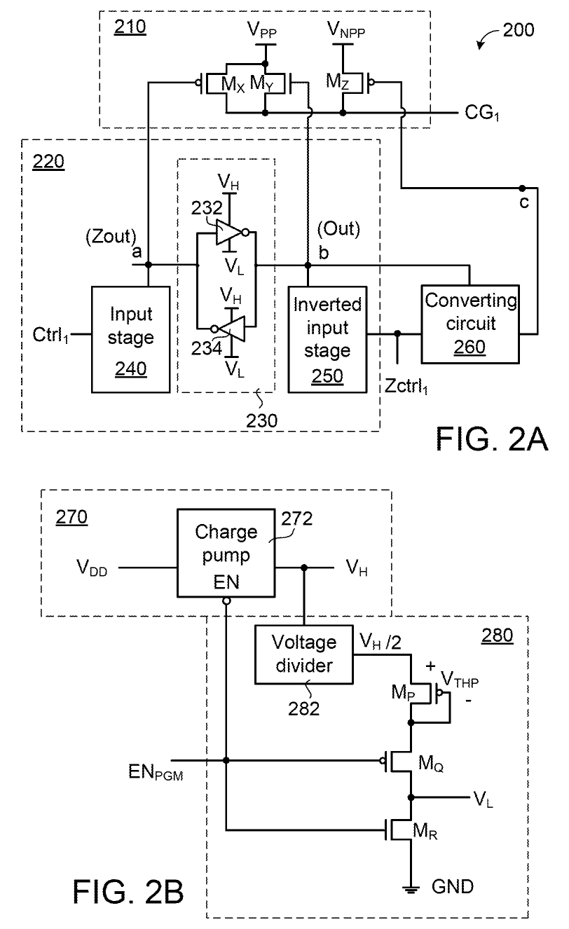

FIG. 2A is a schematic circuit diagram illustrating the switching device of the switching circuit 120 in the nonvolatile memory of the present invention. As shown in FIG. 2A, the switching device 200 includes a selection circuit 210, a level shifter 220 and a converting circuit 260. The level shifter 220 is a latch-type level shifter.

The selection circuit 210 receives the programming voltage V_{PP} and the non-programming voltage V_{NPP}, and the selection circuit 210 is coupled to the control gate line CG₁. The level shifter 220 receives the control signal Ctrl₁ and an inverted control signal Zctrl₁. In addition, the level shifter 220 is connected with the selection circuit 210. The converting circuit 260 receives the inverted control signal Zctrl₁. In addition, the converting circuit 260 is connected with the level shifter 220 and the selection circuit 210. During the program action, the level shifter 220 and the converting circuit 260 control the selection circuit 210 according to the control signal Ctrl₁ and the inverted control signal Zctrl₁. Consequently, the selection circuit 210 provides one of the programming voltage V_{PP} and the non-programming voltage V_{NPP} to the control gate line CG₁. The structure and the operation of the switching device 200 will be described as follows.

The voltage level shifter 220 includes a latch 230, an input stage 240 and an inverted input stage 250. The input stage 240 is connected with the node a and receives a control signal Ctrl₁. The inverted input stage 250 is connected with the node b and receives the inverted control signal Zctrl₁. The control signal Ctrl₁ and the inverted control signal Zctrl₁ are complementary to each other.

The latch 230 includes two inverters 232 and 234. The two power terminals of each of the inverters 232 and 234 receive a high voltage V_{H} and a low voltage V_{L}, respectively. The input terminal of the inverter 232 is connected with the node a. The output terminal of the inverter 232 is connected with the node b. The input terminal of the inverter 234 is connected with the node b. The output terminal of the inverter 234 is connected with the node a. The node b can be served as the output terminal Out of the level shifter 220. The node a can be served as the inverted output terminal Zout of the level shifter 220. Furthermore, the converting circuit 260 is connected with the output terminal Out of the level shifter 220, and the converting circuit 260 receives the inverted control signal Zctrl₁. Furthermore, the output terminal of the converting circuit 260 is connected with the node c.

The selection circuit 210 includes transistors M_{X}, M_{Y} and M_{Z}. The transistors M_{X} and M_{Z} are p-type transistors. The transistor M_{Y} is an n-type transistor. The first drain/source terminals of the transistors M_{X} and M_{Y} receive the programming voltage V_{PP}. The first drain/source terminal of the transistor M_{Z} receives the non-programming voltage V_{NPP}. The second drain/source terminals of the transistors M_{X}, M_{Y} and M_{Z} are coupled to the control gate line CG₁. The gate terminal of the transistor M_{X} is connected with the inverted output terminal Zout of the level shifter 220 (i.e., the node a). The gate terminal of the transistor M_{Y} is connected with the output terminal Out of the level shifter 220 (i.e., the node b). The gate terminal of the transistor M_{Z} is connected with the output terminal of the converting circuit 260 (i.e., the node c). Moreover, the voltage at the node a can be used as a first gate control voltage, the voltage at the node b can be used as a second gate control voltage, and the voltage at the node c can be used as a third gate control voltage. In other words, the inverted output terminal Zout of the level shifter 220 can output the first gate control voltage, the output terminal Out of the level shifter 220 can output the second gate control voltage, and the output terminal of the converting circuit 260 can output the third gate control voltage.

Before the program action, the high voltage V_{H} is equal to the supply voltage V_{DD}. The low voltage V_{L} is equal to the ground voltage (0V). During the program action, the high voltage V_{H} is equal to a target high voltage, and the low voltage V_{L} is equal to a target low voltage. The target high voltage is equal to the maximum value of the programming voltage V_{PP}. The target low voltage is less than a half of the target high voltage. For example, the supply voltage V_{DD} is equal to 2.0V, the target high voltage is equal to 7V, and the target low voltage is equal to 3V.

FIG. 2B is a schematic circuit diagram illustrating a high voltage generator and a low voltage generator of the switching circuit 120 in the nonvolatile memory of the present invention. The switching circuit 120 further includes a high voltage generator 270 and a low voltage generator 280.

The high voltage generator 270 includes a charge pump 272. The input terminal of the charge pump 272 receives the supply voltage V_{DD}. The enable terminal EN of the charge pump 272 receives the program enable signal EN_{PGM}. The output terminal of the charge pump 272 generates the high voltage V_{H}. For example, when the program enable signal EN_{PGM} is in the logic low level state, the program enable signal EN_{PGM} is activated. When the program enable signal EN_{PGM} is in the logic high level, the program enable signal EN_{PGM} is not activated.

The low voltage generator 280 includes a voltage divider 282 and three transistors M_{P}, M_{Q} and M_{R}. The voltage divider 282 is a resistive voltage divider. The transistors M_{P} and M_{Q} are p-type transistors. The transistor M_{R} is an n-type transistor. The input terminal of the voltage divider 282 receives the high voltage V_{H}. The output terminal of the voltage divider 282 generates a divided voltage. For example, the divided voltage is equal to a half the high voltage (i.e., V_{H}/2). The first drain/source terminal of the transistor M_{P} is connected with the output terminal of the voltage divider 282. The second drain/source terminal of the transistor M_{P} is connected with the gate terminal of the transistor M_{P}. The first drain/source terminal of the transistor M_{Q} is connected with the second drain/source terminal of the transistor M_{P}. The gate terminal of the transistor M_{Q} receives the program enable signal EN_{PGM}. The second drain/source terminal of the transistor M_{Q} generates the low voltage V_{L}. The first drain/source terminal of the transistor M_{R} is connected with the second drain/source terminal of the transistor M_{Q}. The gate terminal of the transistor M_{R} receives the program enable signal EN_{PGM}. The second drain/source terminal of the transistor M_{R} is connected with the ground terminal GND.

When the program enable signal EN_{PGM} is not activated, the charge pump 272 in the high voltage generator 270 is disabled. Meanwhile, the high voltage V_{H} generated at the output terminal of the charge pump 272 is equal to the supply voltage V_{DD}. In the low voltage generator 280, the transistor M_{R} is turned on, the transistor M_{Q} is turned off, and the low voltage V_{L} is equal to the ground voltage (0V). In other words, when the program enable signal EN_{PGM} is not activated, the program action has not yet been performed. Meanwhile, the high voltage V_{H} is equal to the supply voltage V_{DD} (2.0V), and the low voltage V_{L} is equal to the ground voltage (0V).

When the program enable signal EN_{PGM} is activated, the charge pump 272 in the high voltage generator 270 is enabled. Meanwhile, the high voltage V_{H} generated at the output terminal of the charge pump 272 is boosted to the target high voltage (e.g., 7V) by the charge pump 272. Furthermore, in the low voltage generator 280, the transistor M_{Q} is turned on, and the transistor M_{R} is turned off. Meanwhile, the low voltage V_{L} is equal to the target low voltage, and the target low voltage is equal to (V_{H}/2-V_{THP}), wherein V_{THP} is the threshold voltage of the transistor M_{P}. For example, V_{THP} is equal to 0.5V. Consequently, the low target voltage is equal to 3V (3.5V - 0.5V). In other words, when the program enable signal EN_{PGM} is activated, the program action is performed. Meanwhile, the high voltage V_{H} is equal to 7V, and the low voltage V_{L} is equal to 3V.

As mentioned above, the high voltage generator 270 and the low voltage generator 280 are operated according to the program enable signal EN_{PGM}. At the moment when the program enable signal EN_{PGM} is activated, the high voltage V_{H} of the level shifter 220 is directly switched from the supply voltage V_{DD} to the target high voltage (e.g., 7V). Similarly, the low voltage V_{L} of the level shifter 220 is directly switched from the ground voltage (0V) to the target low voltage (e.g., 3V).

Furthermore, the low voltage generator 280 receives the high voltage V_{H} from the high voltage generator 270 and divides the high voltage V_{H} to generate the low voltage V_{L}. That is, during the operations of the high voltage generator 270 and the low voltage generator 280, it can be ensured that the high voltage V_{H} is always greater than the low voltage V_{L}.

It is noted that the circuitry structures of the high voltage generator 270 and the low voltage generator 280 are not restricted. The high voltage generator and the low voltage generator can be designed according to the practical requirements of the memory. Consequently, during the program action, the high voltage generator and the low voltage generator generate the target high voltage and the target low voltage, respectively.

In some embodiments, the low voltage generator 280 further includes a load transistor (not shown). The first drain/source terminal of the load transistor is connected to the second drain/source terminal of the transistor M_{Q}, the second drain/source terminal of the load transistor receives the ground voltage GND, and the gate terminal of the load transistor receives a bias voltage. The load transistor is an n-type transistor, having a current driving capability lower than that of the transistor M_{R}. When the program enable signal EN_{PGM} is activated, the transistor M_{R} is turned off. At this time, the load transistor is capable of providing a small sink current path from the output node of the low voltage V_{L} (i.e., the second drain/source terminal of the transistor M_{Q}) to the ground voltage GND, thereby preventing the output node from being in a floating state. Furthermore, when the program enable signal EN_{PGM} is not activated, the transistor M_{R} is still able to pull the output node of the low voltage V_{L} (i.e., the second drain/source terminal of the transistor M_{Q}) down to the ground voltage.

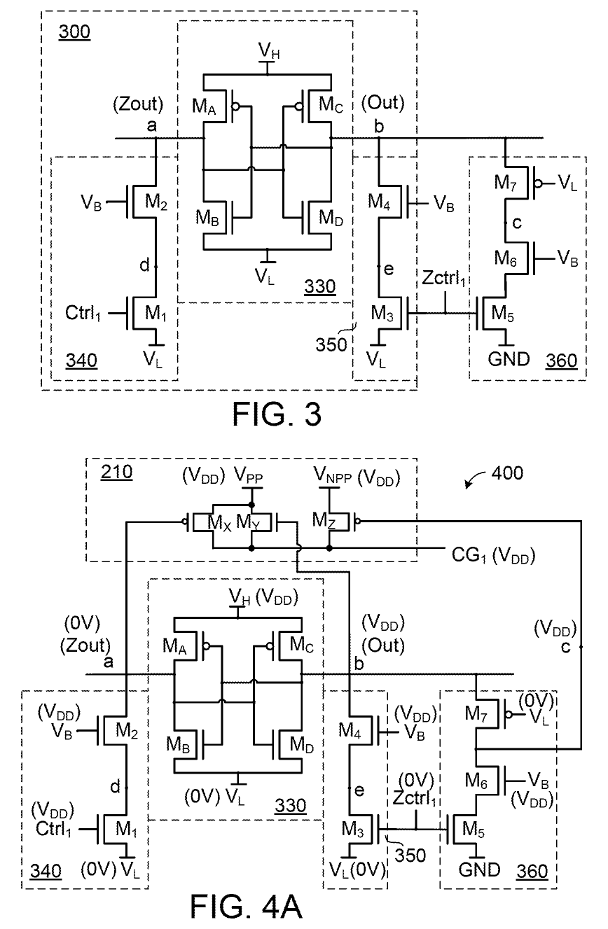

FIG. 3 is a schematic circuit diagram illustrating the level shifter and the converting circuit in the switching device according to a first embodiment of the present invention. As shown in FIG. 3, the level shifter 300 includes a latch 330, an input stage 340 and an inverted input stage 350.

The latch 330 includes transistors M_{A}, M_{B}, M_{C} and M_{D}. The transistors M_{A} and M_{C} are p-type transistors. The transistors M_{B} and M_{D} are n-type transistors. The first source/drain terminal of the transistor M_{A} receives the high voltage V_{H}. The gate terminal of the transistor M_{A} is connected with the node b. The second source/drain terminal of the transistor M_{A} is connected with the node a. The first source/drain terminal of the transistor M_{B} is connected with the node a. The gate terminal of the transistor M_{B} is connected with the node b. The second source/drain terminal of the transistor M_{B} receives the low voltage V_{L}. The first source/drain terminal of the transistor M_{C} receives the high voltage V_{H}. The gate terminal of the transistor M_{C} is connected with the node a. The second source/drain terminal of the transistor M_{C} is connected with the node b. The first drain/source terminal of the transistor M_{D} is connected with the node b. The gate terminal of the transistor M_{D} is connected with the node a. The second drain/source terminal of the transistor M_{D} receives the low voltage V_{L}. The transistor M_{A} and the transistor M_{B} are collaboratively formed as an inverter. The transistor M_{C} and the transistor M_{D} are collaboratively formed as another inverter.

The input stage 340 includes two transistors M₁ and M₂. The transistors M₁ and M₂ are n-type transistors. The gate terminal of the transistor M₁ receives the control signal Ctrl₁. The first drain/source terminal of the transistor M₁ receives low voltage V_{L}. The second drain/source terminal of the transistor M₁ is connected with the node d. The gate terminal of the transistor M₂ receives bias voltage V_{B}. The first drain/source terminal of the transistor M₂ is connected with the node d. The second drain/source terminal of the transistor M₂ is connected with the node a.

The inverted input stage 350 includes two transistors M₃ and M₄. The transistors M₃ and M₄ are n-type transistors. The gate terminal of the transistor M₃ receives the inverted control signal Zctrl₁. The first drain/source terminal of the transistor M₃ receives the low voltage V_{L}. The second drain/source terminal of the transistor M₃ is connected with the node e. The gate terminal of the transistor M₄ receives the bias voltage VB. The first drain/source terminal of the transistor M₄ is connected with the node e. The second drain/source terminal of the transistor M₄ is connected with the node b.

The converting circuit 360 includes transistors M₅, M₆ and M₇. The transistors M₅ and M₆ are n-type transistors. The transistor M₇ is a p-type transistor. The gate terminal of the transistor M₅ receives the inverted control signal Zctrl₁. The first drain/source terminal of the transistor M₅ receives the ground voltage GND. The first drain/source terminal of the transistor M₆ is connected with the second drain/source terminal of the transistor M₅. The gate terminal of the transistor M₆ receives the bias voltage V_{B}. The second drain/source terminal of the transistor M₆ is connected with the node c. The gate terminal of the transistor M₇ receives the low voltage V_{L}. The first drain/source terminal of the transistor M₇ is connected with the node c. The second drain/source terminal of the transistor M₇ is connected with the node b.

When the program enable signal EN_{PGM} is not activated, i.e., before the programming action, the level shifter 300 stores the logic level of the control signal Ctrl₁ in the latch 330. When the program enable signal EN_{PGM} is activated, i.e., the program action is started, the voltages of the output terminal Out and the inverted output terminal Zout of the level shifter 300 will rise according to the logic level stored in the latch 330. Consequently, the operation of the selection circuit 210 will be controlled. That is, during the program action, the voltage of the output terminal Out of the level shifter 300 is one of the target high voltage and the target low voltage, and the voltage of the inverted output terminal Zout of the level shifter 300 is the other of the target high voltage and the target low voltage. For example, the output terminal Out of the level shifter 300 is the target high voltage, and the inverted output terminal Zout of the level shifter 300 is the target low voltage. Alternatively, the output terminal Out of the level shifter 300 is the target low voltage, and the inverted output terminal Zout of the level shifter 300 is the target high voltage.

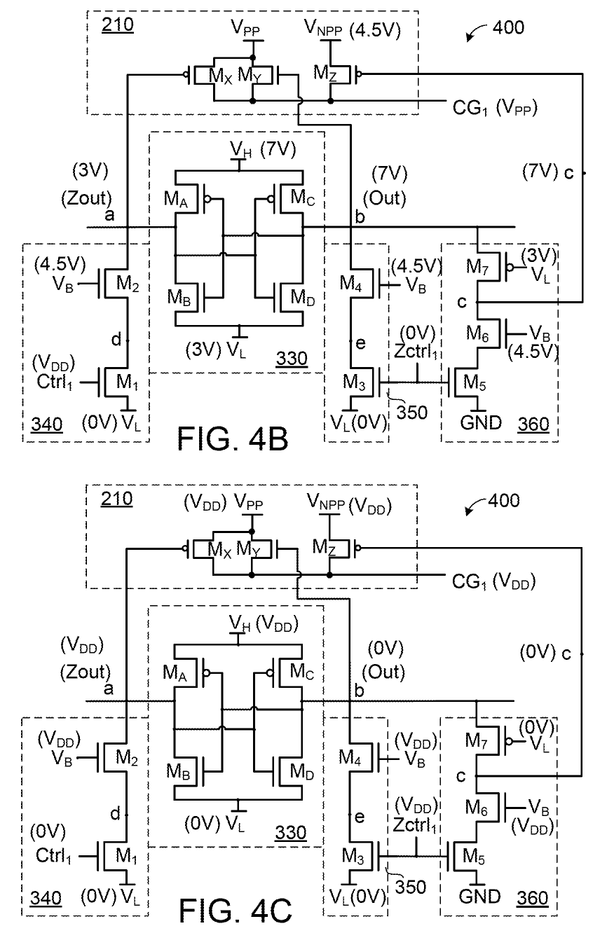

FIGS. 4A, 4B, 4C and 4D are schematic circuit diagrams illustrating the operations of the switching device in the switching circuit of the present invention. The switching device 400 includes the selection circuit 210 and the level shifter 300 and the converting circuit 360 shown in FIG. 3.

Please refer to FIG. 4A. Before the program action is performed, each of the programming voltage V_{PP}, the non-programming voltage V_{NPP} and the high voltage V_{H} is equal to the supply voltage V_{DD}, the bias voltage V_{B} is equal to the supply voltage V_{DD}, and the low voltage V_{L} is equal to the ground voltage (0V). Furthermore, the control signal Ctrl₁ has the logic high level (V_{DD}), and the inverted control signal Zctrl₁ has the logic low level (0V). For example, the supply voltage V_{DD} is 2.0V.

Meanwhile, in the input stage 340, the transistors M₁ and M₂ are turned on. Consequently, the voltage at the node a (i.e., the inverted output terminal Zout of the level shifter) has the logic low level (0V). In the inverted input stage 350, the transistor M₃ is turned off. Consequently, the voltage at the node b (i.e., the output terminal Out of the level shifter) has the logic high level (V_{DD}). In the converting circuit 360, the transistor M5 is turned off, and the transistor M₇ is turned on. Consequently, the voltage at the node c has the logic high level (V_{DD}).

In the selection circuit 210, the voltage at the node a is equal to the ground voltage (0V), and the transistor M_{X} is turned on. The voltage at the node b is the supply voltage V_{DD}, and the transistor M_{Y} is turned on. The voltage at the node c is the supply voltage V_{DD}, and the transistor M_{Z} is turned off. Consequently, the voltage provided to the control gate line CG₁ is supply voltage V_{DD} (i.e., 2.0V). That is, before the program action, the supply voltage V_{DD} provided by the control gate line CG₁ cannot be used for the performing the program action.

Please refer to FIG. 4B. When the program action is performed, the programming voltage V_{PP} is continuously changed. For example, the programming voltage V_{PP} rises from 2V to 7V and then falls back to 2V. The non-programming voltage V_{NPP} is 4.5V. The high voltage V_{H} is equal to the target high voltage (7V). The bias voltage V_{B} is equal to the non-programming voltage V_{NPP} (4.5V). The low voltage V_{L} is equal to the target low voltage (3V). Furthermore, the control signal Ctrl₁ has the logic high level (V_{DD}), and the inverted control signal Zctrl₁ has the logic low level (0V).

When the program action is performed, the high voltage V_{H} rises from the supply voltage V_{DD} to the target high voltage (7V), and the low voltage V_{L} rises from the ground voltage (0V) to the target low voltage (3V). Consequently, the second gate control voltage at the output terminal Out of the level shifter (i.e., the node b) rises to the target high voltage (7V), and the first gate control voltage at the inverted output terminal Zout of the level shifter (i.e., the node a) rises to the target low voltage (3V). Furthermore, in the converting circuit 360, the transistor M₅ is turned off, and the transistor M₇ is turned on. Consequently, the third gate control voltage at the output terminal of the converting circuit 360 (i.e., the node c) is the target high voltage (7V).

In the selection circuit 210, the first gate control voltage at the node a is 3V, and transistor M_{X} is turned on. The second gate control voltageat the node b is 7V, and the transistor M_{Y} is turned on. The third gate control voltage at the node c is 7V, and the transistor M_{Z} is turned off. Consequently, the voltage provided to the control gate line CG₁ is the programming voltage V_{PP}. That is, before the program action, the control signal Ctrl₁ in the logic high level state is provided to the level shifter. When the program action is performed, the switching device 400 provides the programming voltage V_{PP} to the control gate line CG₁. The control gate line CG₁ is transmitted to the corresponding memory cell. Consequently, the memory cell is in the programmed state. The programming voltage V_{PP} rises from 2V to a maximum voltage of 7V and then drops back to 2V. For allowing the changed programming voltage V_{PP} to be transmitted to the control gate line CG₁, two transistors M_{X} and M_{Y} in the selection circuit 210 are used to transmit the programming voltage V_{PP}.

Please refer to FIG. 4C. Before the program action, each of the programming voltage V_{PP}, the non-programming voltage V_{NPP} and the high voltage V_{H} is equal to the supply voltage V_{DD}, the bias voltage V_{B} is equal to the supply voltage V_{DD}, and the low voltage V_{L} is equal to the ground voltage (0V). Furthermore, the control signal Ctrl₁ has the logic low level (0V), and the inverted control signal Zctrl₁ has the logic high level (V_{DD}).

Meanwhile, in the inverted input stage 350, the transistors M₃ and M₄ are turned on. Consequently, the voltage at the node b (i.e., the output terminal Out of the level shifter) has the logic low level (0V). In the input stage 340, the transistor M₁ is turned off. Consequently, the voltage at the node a (i.e., the inverted output terminal Zout of the level shifter) has the logic high level (V_{DD}). In the converting circuit 360, the transistors M₅ and M₆ are turned on, and the transistor M₇ is turned off. The voltage at the output terminal of the converting circuit 360 (i.e., the node c) is 0V.

In the selection circuit 210, the voltage at the node a is the supply voltage V_{DD}, and the transistor M_{X} is turned off. The voltage at the node b is the ground voltage (0V), and the transistor M_{Y} is turned off. The voltage at the node c is the ground voltage (0V), and the transistor M_{Z} is turned on. Consequently, the voltage provided to the control gate line CG₁ is the supply voltage V_{DD} (i.e., 2.0V). In other words, before the program action, the supply voltage V_{DD} transmitted by the control gate line CG₁ cannot be used for performing the program action.

Please refer to FIG. 4D. When the program action is performed, the programming voltage V_{PP} is continuously changed. For example, the programming voltage V_{PP} rises from 2V to 7V and then falls back to 2V. The non-programming voltage V_{NPP} is 4.5V. The high voltage V_{H} is equal to the target high voltage (7V). The bias voltage V_{B} is equal to the non-programming voltage VNPP (4.5V). The low voltage V_{L} is equal to the target low voltage (3V). Furthermore, the control signal Ctrl₁ has the logic low level (0V), and the inverted control signal Zctrl₁ has the logic high level (V_{DD}).

When the program action is performed, the high voltage V_{H} rises from the supply voltage V_{DD} to the target high voltage (7V), and the low voltage V_{L} rises from the ground voltage (0V) to the target low voltage (3V). Consequently, the second gate control voltage at the output terminal Out of the level shifter (i.e., the node b) rises to the target low voltage (3V), and the first gate control voltage at the inverted output terminal Zout of the level shifter (i.e., the node a) rises to the target high voltage (7V). Furthermore, in the converting circuit 360, the transistors M₅ and M₆ are turned on, and the transistor M₇ is turned off. Consequently, the third gate control voltage at the output terminal of the converting circuit 360 (i.e., the node c) is 0V.

In the selection circuit 210, the first gate control voltage at the node a is 7V, and the transistor M_{X} is turned off. The second gate control voltage at the node b is 3V, and the transistor M_{Y} is turned off. The third gate control voltage at the node c is 0V, and the transistor M_{Z} is turned on. Consequently, the voltage provided to the control gate line CG₁ is the non-programming voltage V_{NPP} (i.e., 4.5V). In other words, before the program action, the control signal Ctrl₁ in the logic low level state is provided to the voltage level shifter. During the program action, the switching device 400 can provide the non-programming voltage V_{NPP} (4.5V) to the control gate line CG₁, and the non-programming voltage V_{NPP} can be transmitted to the corresponding memory cell. Consequently, the memory cell becomes the unprogrammed state.

As mentioned above, FIGS. 4A-4D collectively illustrate the switching control method of the switching device 400 under different conditions. Specifically, before the program action, the high voltage V_{H} and the low voltage V_{L} received by the latch 330 are the supply voltage V_{DD} and the ground voltage (0V), respectively. At this time, the latch 330 stores the logical level of the control signal Ctrl₁ in the latch 330.

During the program action, the high voltage V_{H} rises from the supply voltage V_{DD} to the target high voltage (e.g., 7V), and the low voltage V_{L} rises from the ground voltage (0V) to the target low voltage (e.g., 3V). Therefore, when the control signal Ctrl₁ is at a logic high level, the switching device 400 provides the programming voltage V_{PP} to the control gate line CG₁ during the program action (as shown in FIGS. 4A and 4B). Conversely, when the control signal Ctrl₁ is at a logic low level, the switching device 400 provides the non-programming voltage V_{NPP} to the control gate line CG₁ during the program action (as shown in FIGS. 4C and 4D). That is, based on the logic level stored in the latch 330, during program action, the second gate control voltage at the output terminal Out of the level shifter and the first gate control voltage at the inverted output terminal Zout of the level shifter are selected from the target high voltage and the target low voltage. Similarly, based on the logic level stored in the latch 330, the third gate control voltage at the output of the converting circuit 360 is selected from the target high voltage and the ground voltage.

Furthermore, since the high voltage V_{H} rises from the supply voltage V_{DD} to the target high voltage (e.g., 7V) and the low voltage V_{L} rises from the ground voltage (V) to the target low voltage (e.g., 3V), the gate-to-source and gate-to-drain voltages across the transistors M_{X}, M_{Y} and M_{Z} in the selection circuit 210 are always maintained within the safe operating area (SOA), thereby preventing the transistors M_{X}, M_{Y} and M_{Z} from being damaged by excessive voltage stresses.

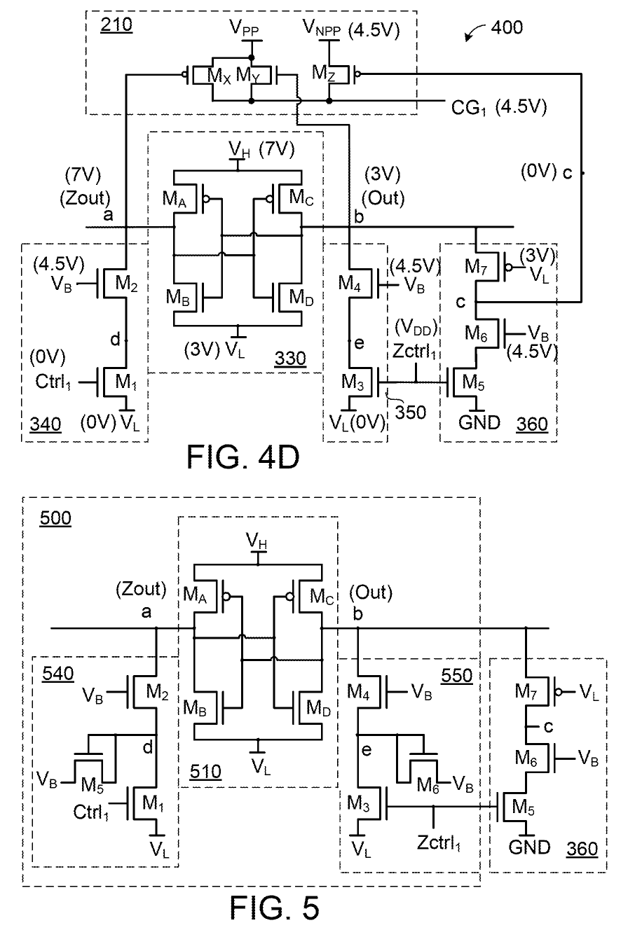

It is noted that the level shifter in the switching device can be modified. FIG. 5 is a schematic circuit diagram illustrating the level shifter and the converting circuit in the switching device according to a second embodiment of the present invention. When compared with the level shifter 300 of the first embodiment, the input stage 540 in the level shifter 500 further includes a transistor M₅, and the inverted input stage 550 further includes a transistor M₆. The transistors M₅ and M₆ are n-type transistors.

In the input stage 540, the first drain/source terminal of the transistor M₅ receives the bias voltage V_{B}, and the second drain/source terminal and the gate terminal of the transistor M₅ are connected with the node d. In the inverted input stage 550, the first drain/source terminal of the transistor M₆ receives the bias voltage V_{B}, and the second drain/source terminal and the gate terminal of the transistor M₆ are connected with the node e. During the operation of the level shifter 500, the transistor M₅ can prevent the node d in the input stage 540 from becoming the floating state. Similarly, the transistor M₆ can prevent the node e in the inverted input stage 550 from becoming the floating state. The operation of the level shifter 500 in FIG. 5 is similar to that of the level shifter in FIG. 3 and will not be redundantly described herein.

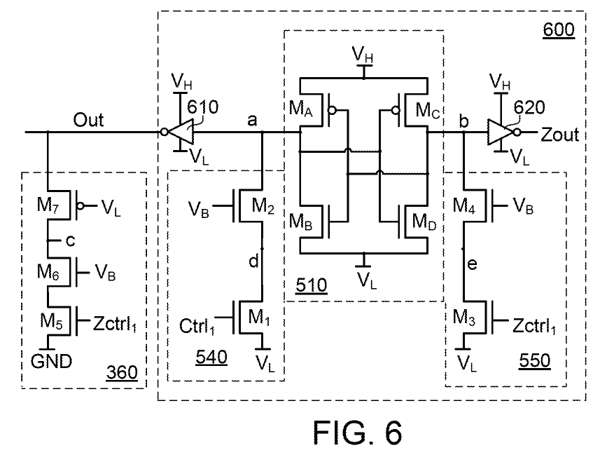

FIG. 6 is a schematic circuit diagram illustrating the level shifter and the converting circuit in the switching device according to a third embodiment of the present invention. When compared with the level shifter 300 of the first embodiment, the level shifter 600 further includes two inverters 610 and 620. The two power terminals of each of the inverters 610 and 620 receive the high voltage V_{H} and the low voltage V_{L}, respectively. The input terminal of the inverter 610 is connected with the node a. The output terminal of the inverter 610 can be served as the output terminal Out of the level shifter 600. The input terminal of the inverter 620 is connected with the node b. The output terminal of the inverter 620 can be served as the inverted output terminal Zout of the level shifter 600. Furthermore, the converting circuit 360 is connected with the output terminal Out of the level shifter 600. The operation of the level shifter 600 in FIG. 6 is similar to that of the level shifter in FIG. 3 and will not be redundantly described herein.

The present invention provides a switching circuit and an associated level shifter for a nonvolatile memory. Since the maximum value of the programming voltage V_{PP} is very high (e.g., 7V) during the program action, the transistors M_{X} and M_{Y} in the selection circuit may be damaged by excessive voltage stresses. In accordance with the present invention, a level shifter is designed in the switching circuit. Before the program action, the logic level of the control signal Ctrl₁ is stored in a latch of the level shifter. During the program action, the voltage at the output terminal of the level shifter is increased according to the logic level in the latch and is used to control the selection circuit. Consequently, all transistors M_{X}, M_{Y} and M_{Z} in the selection circuit can be operated normally within a safe operating area (SOA).

Furthermore, the actual voltage values of the programming voltage V_{PP}, the non-programming voltage V_{NPP} and the bias voltage V_{B} are not restricted. For example, similar to FIG. 2B, a bias voltage generator is designed in the nonvolatile memory. According to the practical requirements, the bias voltage generator can generate different voltage values of the bias voltage V_{B} before and after the program action.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A switching circuit of a nonvolatile memory comprising a plurality of switching devices, the plurality of switching devices being respectively connected with a plurality of control gate lines in a memory cell array, a first switching device of the switching circuit being coupled to a first control gate line, the first switching device comprising:
a selection circuit receiving a programming voltage and a non-programming voltage, wherein the selection circuit is coupled to the first control gate line;
a level shifter receiving a first control signal and a first inverted control signal, and connected with the selection circuit, wherein the first control signal and the first inverted control signal are complementary to each other;
a converting circuit receiving the first inverted control signal, and connected with the level shifter and the selection circuit; and
wherein when a program action is performed, the level shifter and the converting circuit control the selection circuit according to the first control signal and the first inverted control signal, so that the selection circuit provides one of the programming voltage and the non-programming voltage to the first control gate line.

2. The switching circuit as claimed in claim 1, wherein the level shifter comprises:
a latch, wherein a first power terminal of the latch receives a high voltage, a second power terminal of the latch receives a low voltage, and the latch is connected with a first node and a second node;
an input stage connected with the first node, wherein the input stage receives the first control signal; and
an inverted input stage connected with the second node, wherein the inverted input stage receives the first inverted control signal,
wherein before the program action is performed, the high voltage is a supply voltage, the low voltage is a ground voltage, and a logic level of the first control signal is stored in the latch,
wherein when the program action is performed, the high voltage is a target high voltage, and the low voltage is a target low voltage, wherein according to the logic level stored in the latch, a voltage at the first node is one of the target high voltage and the target low voltage, and a voltage of the second node is the other of the target high voltage and the target low voltage.

3. The switching circuit as claimed in claim 2, wherein the selection circuit comprises:
a first transistor, wherein a first drain/source terminal of the first transistor receives the programming voltage, a gate terminal of the first transistor is connected with the first node, and a second drain/source terminal of the first transistor is coupled to the first control gate line;
a second transistor, wherein a first drain/source terminal of the second transistor receives the programming voltage, a gate terminal of the second transistor is connected with the second node, and a second drain/source terminal of the second transistor is coupled to the first control gate line; and
a third transistor, wherein a first drain/source terminal of the third transistor receives the non-programming voltage, a gate terminal of the third transistor is connected with a third node, and a second drain/source terminal of the third transistor is coupled to the first control gate line, wherein an output terminal of the converting circuit is connected with the third node,
wherein the first transistor and the third transistor are p-type transistors, and the second transistor is an n-type transistor.

4. The switching circuit as claimed in claim 2, wherein the switching circuit further comprises a low voltage generator and a high voltage generator, wherein before the program action is performed, the high voltage generator provides the supply voltage as the high voltage, and the low voltage generator provides the ground voltage as the low voltage, wherein when the program action is performed, the high voltage generator provides the target high voltage as the high voltage, and the low voltage generator provides the target low voltage as the low voltage.

5. The switching circuit as claimed in claim 4, wherein the high voltage generator includes a charge pump, wherein an input terminal of the charge pump receives the supply voltage, an enable terminal of the charge pump receives a program enable signal, and an output terminal of the charge pump generates the high voltage, wherein when the program enable signal is not activated, the charge pump is disabled, and the high voltage is equal to the supply voltage, wherein when the program enable signal is activated, the charge pump is enabled, and the high voltage is equal to the target high voltage.

6. The switching circuit as claimed in claim 4, wherein the low voltage generator comprises:
a voltage divider, wherein an input terminal of the voltage divider receives the high voltage, and an output terminal of the voltage divider generates a divided voltage;
a first transistor, wherein a first drain/source terminal of the first transistor is connected with the output terminal of the voltage divider, and a gate terminal of the first transistor is connected with a second drain/source terminal of the first transistor;
a second transistor, wherein a first drain/source terminal of the second transistor is connected with the second drain/source terminal of the first transistor, a gate terminal of the second transistor receives the program enable signal, and a second drain/source terminal of the second transistor generates the low voltage;
a third transistor, wherein a first drain/source terminal of the third transistor is connected with the second drain/source terminal of the second transistor, a gate terminal of the third transistor receives the program enable signal, and a second drain/source terminal of the third transistor receives a ground voltage,
wherein the first transistor and the second transistor are p-type transistors, and the third transistor is an n-type transistor,
wherein when the program enable signal is not activated, the low voltage is equal to the ground voltage, wherein when the program enable signal is activated, the low voltage is equal to the target low voltage.

7. The switching circuit as claimed in claim 6, wherein the low voltage generator further comprises:
a load transistor, wherein a first drain/source terminal of the load transistor is connected with the second drain/source terminal of the second transistor, a gate terminal of the load transistor receives a bias voltage, and a second drain/source terminal of the load transistor receives the ground voltage,
wherein the load transistor is an n-type transistor, and a current driving capability of the load transistor is smaller than a current driving capability of the third transistor,
wherein when the program enable signal is not activated, the third transistor pulls the second drain/source terminal of the second transistor down to the ground voltage,
wherein when the program enable signal is activated, the load transistor provides a current path from the second drain/source terminal of the second transistor to the ground voltage.

8. The switching circuit as claimed in claim 2, wherein the input stage comprises:
a first transistor, wherein a first drain/source terminal of the first transistor receives the low voltage, a gate terminal of the first transistor receives the first control signal, and a second drain/source terminal of the first transistor is connected with a fourth node; and
a second transistor, wherein a first drain/source terminal of the second transistor is connected with the fourth node, a gate terminal of the second transistor receives a bias voltage, and a second drain/source terminal of the second transistor is connected with the first node,
wherein the first transistor and the second transistor are n-type transistors.

9. The switching circuit as claimed in claim 8, wherein the input stage further comprises:
a third transistor, wherein a first drain/source terminal of the third transistor receives the bias voltage, and a gate terminal and a second drain/source terminal of the third transistor are connected with the fourth node, wherein the third transistor is an n-type transistor,
wherein before the program action is performed, the bias voltage is equal to the supply voltage, wherein when the program action is performed, the bias voltage is equal to the non-programming voltage.

10. The switching circuit as claimed in claim 8, wherein the inverted input stage comprises:
a third transistor, wherein a first drain/source terminal of the third transistor receives the low voltage, a gate terminal of the third transistor receives the first inverted control signal, and a second drain/source terminal of the third transistor is connected to a fifth node; and
a fourth transistor, wherein a first drain/source terminal of the fourth transistor is connected with the fifth node, a gate terminal of the fourth transistor receives the bias voltage, and a second drain/source terminal of the fourth transistor is connected with the second node,
wherein the third transistor and the fourth transistor are n-type transistors.

11. The switching circuit as claimed in claim 10, wherein the inverted input stage further comprises:
a fifth transistor, wherein a first drain/source terminal of the fifth transistor receives the bias voltage, and a gate terminal and a second drain/source terminal of the fifth transistor are connected with the fifth node, wherein the fifth transistor is an n-type transistor,
wherein before the program action is performed, the bias voltage is equal to the supply voltage, wherein when the program action is performed, the bias voltage is equal to the non-programming voltage.

12. The switching circuit as claimed in claim 2, wherein the converting circuit comprises:
a first transistor, wherein a first drain/source terminal of the first transistor receives the ground voltage, and a gate terminal of the first transistor receives the first inverted control signal;
a second transistor, wherein a first drain/source terminal of the second transistor is connected with a second drain/source terminal of the first transistor, a gate terminal of the second transistor receives a bias voltage, and a second drain/source terminal of the second transistor is connected with the third node; and
a third transistor, wherein a first drain/source terminal of the third transistor is connected with the third node, a gate terminal of the third transistor receives the low voltage, and a second drain/source terminal of the third transistor is connected with the second node,
wherein the first transistor and the second transistor are n-type transistors, and the third transistor is a p-type transistor.

13. The switching circuit as claimed in claim 2, wherein the level shifter comprises:
a first inverter, wherein a first power terminal of the first inverter receives the high voltage, a second power terminal of the first inverter receives the low voltage, an input terminal of the first inverter is connected with the first node, and an output terminal of the first inverter is served as an output terminal of the level shifter; and
a second inverter, wherein a first power terminal of the second inverter receives the high voltage, a second power terminal of the second inverter receives the low voltage, an input terminal of the second inverter is connected with the second node, and an output terminal of the second inverter is served as an inverted output terminal of the level shifter.

14. The switching circuit as claimed in claim 13, wherein the converting circuit comprises:
a first transistor, wherein a first drain/source terminal of the first transistor receives the ground voltage, and a gate terminal of the first transistor receives the first inverted control signal;
a second transistor, wherein a first drain/source terminal of the second transistor is connected with a second drain/source terminal of the first transistor, a gate terminal of the second transistor receives a bias voltage, and a second drain/source terminal of the second transistor is connected with the third node; and
a third transistor, wherein a first drain/source terminal of the third transistor is connected with the third node, a gate terminal of the third transistor receives the low voltage, and a second drain/source terminal of the third transistor is connected with the output terminal of the level shifter,
wherein the first transistor and the second transistor are n-type transistors, and the third transistor is a p-type transistor.

15. A switching control method of a switching circuit within a nonvolatile memory, the switching circuit including a plurality of switching devices respectively coupled to a plurality of control gate lines of a memory cell array, a first switching device of the switching devices is coupled to a first control gate line, and the first switching device comprising a selection circuit, a level shifter and a converting circuit, wherein the switching control method comprises steps of:
(a1) before a program action, providing a supply voltage as a high voltage, providing a ground voltage as a low voltage, and storing a logic level of a control signal in a latch of the level shifter, wherein the high voltage and the low voltage are received by the latch;
(a2) during the program action, raising the high voltage from the supply voltage to a target high voltage, and raising the low voltage from the ground voltage to a target low voltage, wherein the target low voltage is higher than the ground voltage and lower than the target high voltage;
(a3) according to the logic level stored in the latch, setting a first gate control voltage at a first output terminal of the level shifter, setting a second gate control voltage at a second output terminal of the level shifter, and setting a third gate control voltage at an output terminal of the converting circuit, wherein the first gate control voltage is one of the target high voltage and the target low voltage, the second gate control voltage is the other of the target high voltage and the target low voltage, and the third gate control voltage is one of the target high voltage and the ground voltage; and
(a4) according to the first gate control voltage, the second gate control voltage and the third gate control voltage, the selection circuit outputting a programming voltage or a non-programming voltage to the first control gate line of the memory cell array.

16. The switching control method as claimed in claim 15, wherein the selection circuit includes a first p-type transistor, an n-type transistor and a second p-type transistor, a first drain/source terminal of the first p-type transistor receives the programming voltage, a gate terminal of the first p-type transistor receives the first gate control voltage, a second drain/source terminal of the first p-type transistor is coupled to the first control gate line, a first drain/source terminal of the n-type transistor receives the programming voltage, a gate terminal of the n-type transistor receives the second gate control voltage, a second drain/source terminal of the n-type transistor is coupled to the first control gate line, a first drain/source terminal of the second p-type transistor receives the non-programming voltage, a gate terminal of the second p-type transistor receives the third gate control voltage, and a second drain/source terminal of the second p-type transistor is coupled to the first control gate line,
wherein the step (a4) further comprises:
(b1) turning on the first p-type transistor, turning on the n-type transistor and turning off the second p-type transistor for providing the programming voltage to the first control gate line when the control signal is at a first logic level, the first gate control voltage is the target low voltage, the second gate control voltage is the target high voltage and the third gate control voltage is the target high voltage; and
(b2) turning off the first p-type transistor, turning off the n-type transistor and turning on the second p-type transistor for providing the non-programming voltage to the first control gate line when the control signal is at a second logic level, the first gate control voltage is the target high voltage, the second gate control voltage is the target low voltage and the third gate control voltage is the ground voltage.
